(19) United States
(12) Patent Application Publication
(10) Pub. No.: US 2009/0174296 A1
(43) Pub. Date: Jul. 9, 2009

(54) Computer frame

(75) Inventor: Han Liu, Fremont, CA (US)

Correspondence Address: BACON & THOMAS, PLLC, 625 SLATERS LANE, FOURTH FLOOR, ALEXANDRIA, VA, 22314-1176, US

(73) Assignee: ANTEC, INCORPORATED, Fremont, CA (US)

(21) Appl. No.: 12/007,182

(22) Filed: Jan. 8, 2008

(51) Int. Cl. H05K 5/03; A47B 81/00

(52) U.S. Cl. 312/223.2

(57) ABSTRACT

A computer frame has a body and multiple support assemblies. The body has a housing and multiple mounting legs and may accommodate a fan. The housing has a sidewall. The mounting legs are attached to and protrude down from the sidewall. The support assemblies are attached to and hold the body to allow a computer to be mounted under the body. Therefore, the computer frame allows efficient air circulation and makes maintaining a computer system mounted in the computer frame easy.

### BACKGROUND OF THE INVENTION

1. Field of the Invention

The present invention relates to a computer frame, and more particularly, to a computer frame that provides efficient air circulation.

2. Description of the Prior Arts

With virtual universal usage of computers in modern society, various casings have been designed to accommodate different computer systems designed to satisfy the different requirements of people using the computers.

Commonly seen computer casings usually comprise an enclosed metal housing to hold a computer system, a power supply and a fan. The computer system usually includes a mainboard, hard discs, a CD-ROM drive, a CD burner video card, a network card, peripheral interface cards, etc. The computer system generates heat while operating. Hot air inside the housing is blown out by the fan to dissipate heat and keep the temperature inside the computer casing from getting excessively high.

However, the introduction of more powerful CPU's and additional active component puts a tremendous burden on the fan, which usually fails to completely dissipate the heat since the computer casing is enclosed. This results in elevated temperatures and component failures leading to computer system crashes during extended computer operation.

Moreover, repairs and modifications to the computer system require that the existing computer casing be disassembled to gain access to individual components of the computer system. In addition to being inconvenient and removing the cover makes a person working on the computer susceptible to being injured sharp edges of existing computer casings.

To overcome the shortcomings, the present invention provides a computer frame to mitigate or obviate the aforementioned problems.

### SUMMARY OF THE INVENTION

The main objective of the invention is to provide a computer frame that provides efficient air circulation.

A computer frame in accordance with the present invention comprises a body and multiple support assemblies. The body has a housing and multiple mounting legs and may accommodate a fan. The housing has a sidewall. The mounting legs are attached to and protrude down from the sidewall. The support assemblies are attached to and hold the body to allow a computer to be mounted under the body. Therefore, the computer frame allows efficient air circulation and makes maintaining a computer system mounted in the computer frame easy.

Other objectives, advantages and novel features of the invention will become more apparent from the following detailed description when taken in conjunction with the accompanying drawings.

### BRIEF DESCRIPTION OF THE DRAWINGS

FIG. 1 is an exploded perspective view of a first embodiment of a computer frame in accordance with the present invention;

FIG. 2 is a perspective view of the computer frame in FIG. 1;

FIG. 3 is a partially exploded perspective view of a second embodiment of a computer frame in accordance with the present invention;

FIG. 4 is a perspective view of the computer frame in FIG. 3; and

FIG. 5 is an enlarged perspective view of part of a support assembly of the computer frame in FIG. 3.

### DETAILED DESCRIPTION OF THE PREFERRED EMBODIMENTS

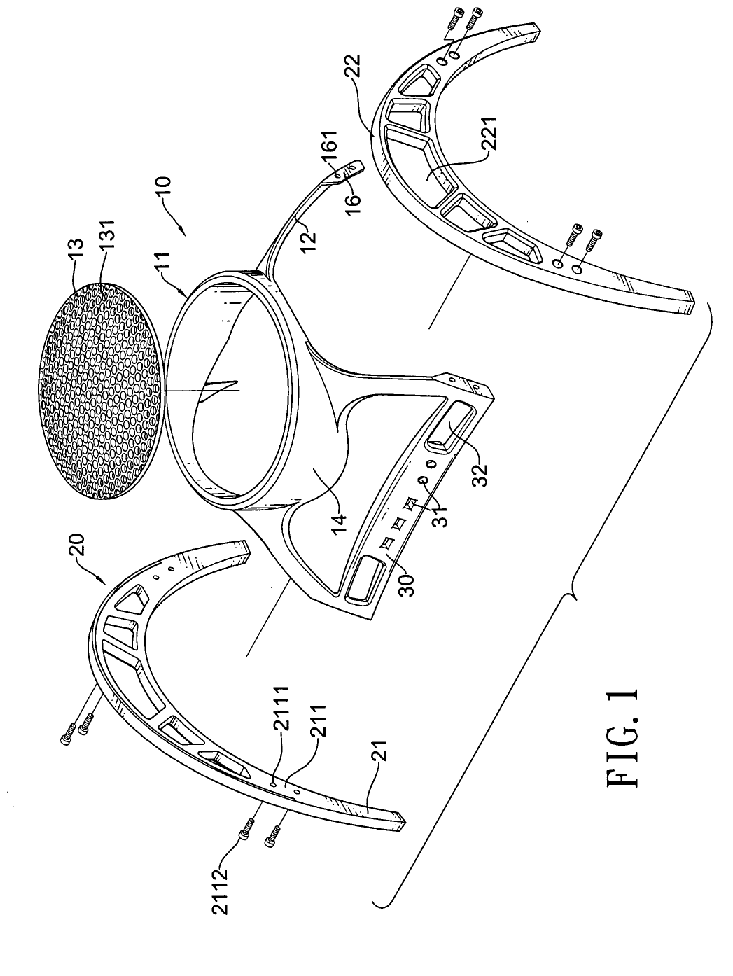

With reference to the FIG. 1, a computer frame in accordance with the present invention comprises a body (10), multiple support assemblies (20) and an optional control panel (30).

The body (10) has a housing (11) and multiple mounting legs (12).

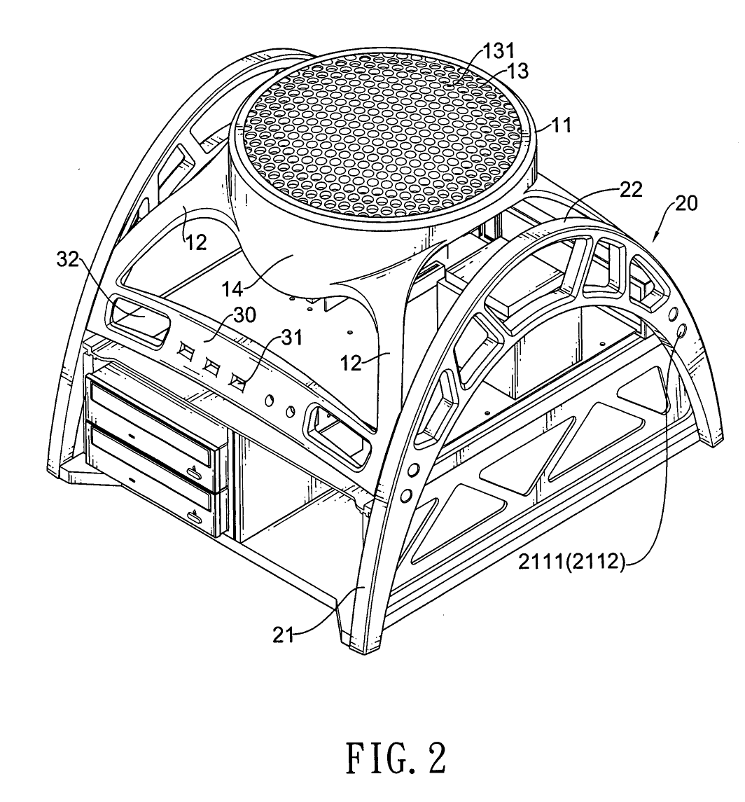

With further reference to FIG. 2, the housing (11) has a top, a cover (13) and a sidewall (14). The cover (13) has an outer edge, may be circular and may have multiple vents (131). The vents (131) are formed through the cover (13). The sidewall (14) attaches to and protrudes down from the outer edge of the cover (13) and forms an opening in which a fan (not shown) may be mounted.

The mounting legs (12) are attached to and protrude down from the sidewall (14), and each mounting leg (12) has an outer edge, a distal end, an optional contact surface (16) and multiple optional connecting holes (161). The contact surface (16) is flat and is formed on the outer edge of the mounting leg (12) adjacent to the distal end of the mounting leg (12). The connecting holes (161) are formed in the contact surface (16) and may be threaded.

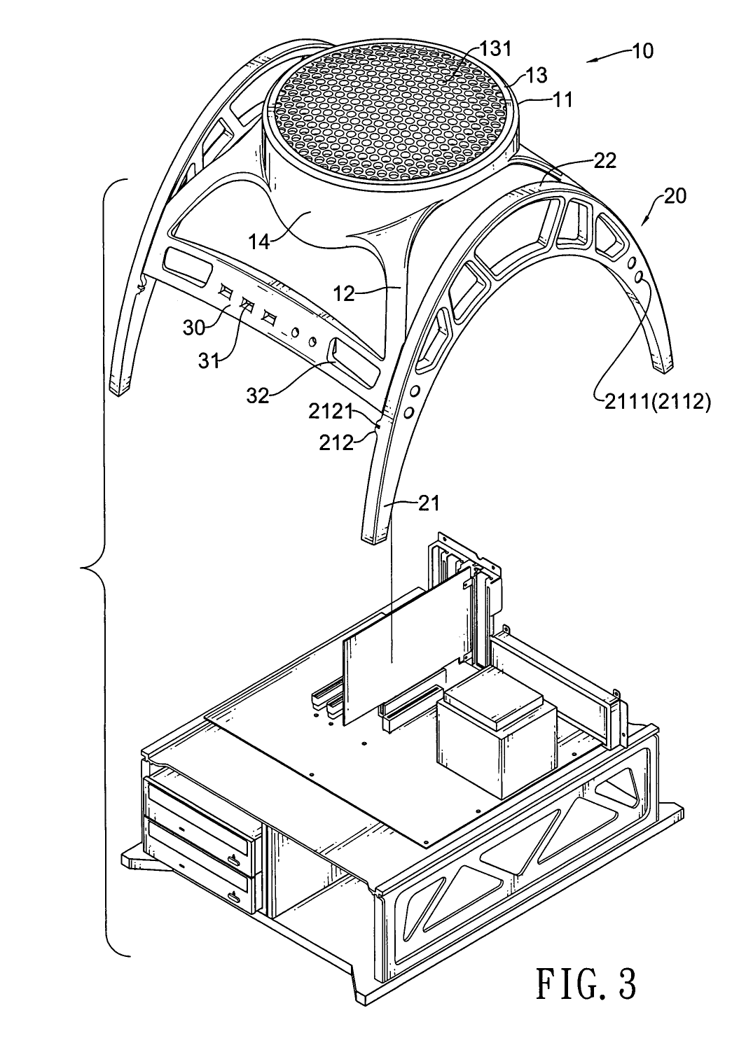

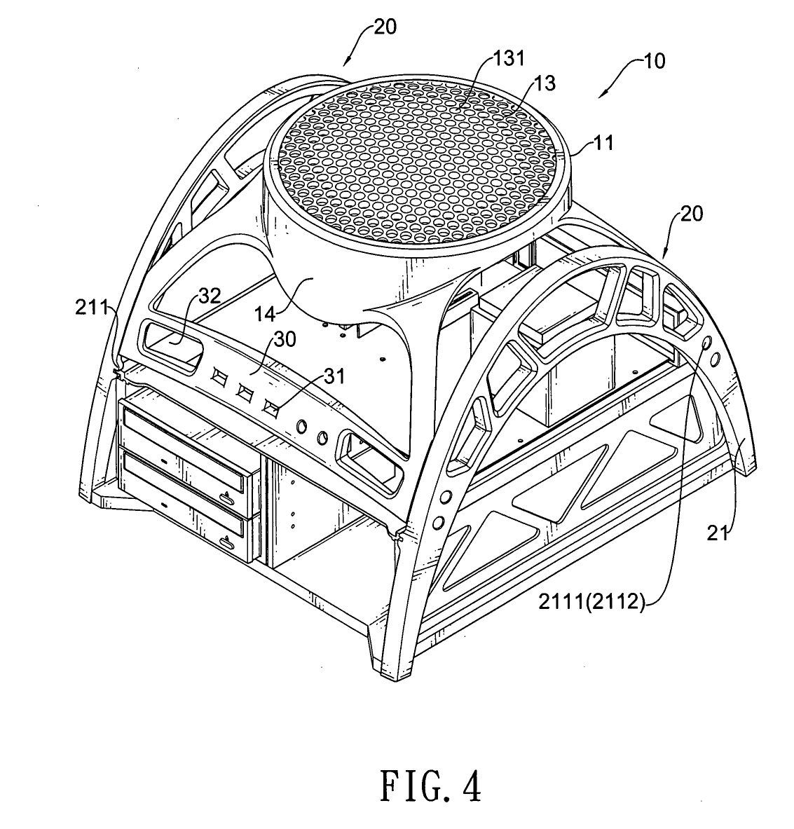

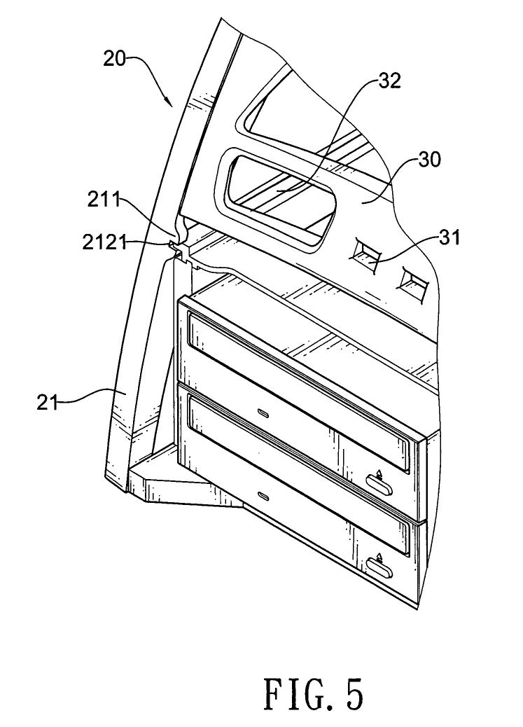

With further reference to FIGS. 3 to 5, the support assemblies (20) are attached to and hold the body (10) to allow a computer to be mounted under the body (10). Each support assembly (20) may be arch-shaped and has a pair of elongated feet (21) and an optional connecting arch (22).

The elongated feet (21) are attached respectively to and protrude down from adjacent mounting legs (12), and each elongated foot (21) has an upper end, an inside surface, an optional connecting surface (211) and an optional mounting notches (212).

The connecting surface (211) is formed on the inside surface adjacent to the upper end and is attached to the contact surface (16) on the mounting leg (12), and each connecting surface (211) has multiple optional through holes (2111) and multiple optional fasteners (2112). The through holes (2111) are formed through the connecting surface (211) and correspond respectively to the connecting holes (161) on the adjacent contact surface (16) of the mounting leg (12). The fasteners (2112) are mounted respectively through the through holes (2111), connect respectively to the connecting holes (161), may be threaded and screw respectively into the connecting holes (161).

The mounting notch (212) is formed on and protrudes from the inside surface of the elongated foot (21) near the upper end and has a lobe and a slot (2121). The lobe is formed on and protrudes slightly from the elongated foot (21). The slot (2121) is formed horizontally in the lobe and detachably holds a computer chassis.

The connecting arch (22) is curved, attaches to adjacent elongated feet (21) and has two ends and multiple optional decorative openings (221). The ends correspond and are attached respectively to the upper ends of adjacent elongated feet (21). The decorative openings (221) are formed transversely through the connecting arch (22) and allow air and heat to pass through the connecting arch (22).

The control panel (30) is mounted between adjacent elongated feet (21), may be attached to adjacent mounting legs (12) and has two ends, multiple holes (31) and multiple optional decorative holes (32). The holes (31) allow control indicators and devices such as lights, meters, switches, knobs and the like to be mounted on the control panel (30). The decorative holes (32) are formed through the control panel (30) and allow air and heat to pass through the control panel (30).

The computer frame as described has advantages of being open, allowing heat generated by a computer mounted in the computer frame to readily dissipate and accommodating any computer mounting configurations.

Even though numerous characteristics and advantages of the present invention have been set forth in the foregoing description, together with details of the structure and features of the invention, the disclosure is illustrative only. Changes may be made in the details, especially in matters of shape, size, and arrangement of parts within the principles of the invention to the full extent indicated by the broad general meaning of the terms in which the appended claims are expressed.

What is claimed is:

1. A computer frame comprising:
a body having
a housing having
a top;
a cover having an outer edge; and
a sidewall attaching to and protruding down from the outer edge of the cover and forming an opening; and
multiple mounting legs being attached to and protruding down from the sidewall, and each mounting leg having
an outer edge; and
a distal end; and
multiple support assemblies being attached to and holding the body, and each support assembly having a pair of elongated feet, the elongated feet being attached respectively to and protruding down from adjacent mounting legs, and each elongated foot having
an upper end; and an inside surface.

2. The computer frame as claimed in claim 1 further comprising a control panel being mounted between adjacent elongated feet and having
two ends; and
multiple holes.

3. The computer frame as claimed in claim 1, wherein the cover is circular.

4. The computer frame as claimed in claim 1, wherein the cover has multiple vents being formed through the cover.

5. The computer frame as claimed in claim 1, wherein
each mounting leg further has a contact surface being flat and being formed on the outer edge of the mounting leg adjacent to the distal end of the mounting leg; and
each elongated foot further has a connecting surface being formed on the inside surface of the elongated foot adjacent to the upper end of the elongated foot and being attached to the contact surface on the adjacent mounting leg.

6. The computer frame as claimed in claim 1, wherein each support assembly is arch-shaped and further has a connecting arch being curved, attaching to adjacent elongated feet and having two ends corresponding and being attached respectively to the upper ends of the adjacent elongated feet.

7. The computer frame as claimed in claim 1, wherein each elongated foot further has a mounting notch being formed on and protruding from the inside surface of the elongated foot near the upper end of the elongated foot and having
a lobe being formed on and protruding slightly from the elongated foot; and
a slot being formed horizontally in the lobe.

8. The computer frame as claimed in claim 2, wherein the control panel is attached to adjacent mounting legs.

9. The computer frame as claimed in claim 2, wherein the control panel further has multiple decorative holes being formed through the control panel.

10. The computer frame as claimed in claim 5, wherein each mounting leg further has multiple connecting holes being formed in the contact surface.

11. The computer frame as claimed in claim 5, wherein each connecting surface further has
multiple through holes being formed through the connecting surface and corresponding respectively to the connecting holes on the adjacent contact surface of the mounting leg; and
multiple fasteners being mounted respectively through the through holes and connecting respectively to the connecting holes.

12. The computer frame as claimed in claim 6, wherein each connecting arch further has multiple decorative openings being formed transversely through the connecting arch.

13. The computer frame as claimed in claim 11, wherein
the connecting holes are threaded; and
the fasteners are threaded and screw respectively into the connecting holes.
